(19) United States
(12) Patent Application Publication
(10) Pub. No.: US 2013/0346010 A1
(43) Pub. Date: Dec. 26, 2013

(54) ELECTRIC VEHICLE CHARGER TESTING SYSTEMS

(71) Applicant: STEPHEN P. SCHULZ, HUNTINGTON BEACH, CA (US)

(72) Inventor: STEPHEN P. SCHULZ, HUNTINGTON BEACH, CA (US)

(73) Assignee: GREEN CHARGE NETWORKS LLC, Huntington Beach, CA (US)

(21) Appl. No.: 13/531,442

(22) Filed: Jun. 22, 2012

(51) Int. Cl. G01R 29/00; G06F 19/00

(52) U.S. Cl. 702/122; 324/602

(57) ABSTRACT

Systems, methods, and apparatus relating to electric vehicle (EV) charger testing systems are disclosed and claimed herein. Exemplary systems comprise an EV charger connection interface having communication and power connections complying with one or more EV charging protocols, an electrical load module connected to power connections, and charging protocol compliance signal generators connected to the charger connection interface for simulation of a connection between an EV and an EV charger. Testing systems may be used to monitor, record, and profile the output of an EV charger and determine compliance of the output with one or more EV charging protocols. Additionally, methods related to testing and analyzing charge output of an EV charger are disclosed, including determining which of multiple charging protocols to use while testing the charger.

### BACKGROUND

Systems of the present invention are directed to the fields of electrical devices, electric vehicles, energy storage charging equipment and standards, testing devices, and related fields.

Electric vehicles (EVs) such as battery EVs (BEVs), plug-in hybrid EVs (PHEVs), and other vehicles which use electricity as a source of power for their movement have grown in prominence as their popularity and availability has increased over time. These EVs have high requirements for electrical infrastructure and support, including electric vehicle supply equipment (EVSE), which includes EV chargers, charging stations, safety equipment, connectors, and other devices used to resupply electric charge to an EV when its battery storage is diminished.

The emerging nature of the EV market and fast-paced introduction of new models has proliferated the production of a number of various charging protocols and connectors to serve the needs of many different kinds of vehicles. As a result, the EVSE market and EVSE users are unsettled concerning the devices that future EVs will use to receive charge in the future, and various EVs use a wide variety of different standards for charging and connection to EVSE. Therefore, owners and operators of existing EVSE are forced to provide charging stations that support multiple competing charging standards.

In most cases, charging equipment requires a safety confirmation signal of some kind from an EV before power is provided to a power line in a charging connector, so existing systems require a discharged EV to test the charging equipment. EVs are expensive, and are not easily and quickly discharged to allow for frequent and repeated controlled EVSE testing. As a result, it is difficult to test and evaluate the operation, safety, and compliance with the charging protocols with which they are designed to provide. Other charging station testing equipment may be used, such as communication terminals, oscilloscopes, power supplies, and network analyzers, but it is mainly configured to support single charging standards. This makes it bulky and expensive to test multiple protocols, particularly when the protocols have hardware differences in their connectors, load requirements, and supported communication channels.

Accordingly, there is a need for a charging station testing system that may have one or more of the following desired attributes: is easy and safe to use with EV charging stations, supports multiple charging protocols, is capable of imitating the communication and load of multiple types and models of electric vehicles, is more efficient than using actual EVs for testing, and is configured to be able to keep up with the rapid pace of EV charging protocol development.

### BRIEF SUMMARY

In one embodiment, an electric vehicle (EV) charger compliance test system is provided, comprising an EV charger connection interface having one or more communication connections and one or more power connections, wherein one or more of the communication connections and one or more of the power connections comply with a first EV charging protocol, and wherein one or more of the communication connections and one or more of the power connections comply with a second EV charging protocol. The EV charger compliance test system further comprises a load module connected to the power connections, a first charging protocol compliance signal generator connected to one or more of the communication connections in compliance with the first EV charging protocol, and a second charging protocol compliance signal generator connected to one or more of the communication connections in compliance with the second EV charging protocol.

In another embodiment, the EV charger connection interface supports two different EV charging plugs, and the EV charging plugs are compliant with different EV charging protocols.

In another embodiment, the EV charger connection interface comprises two separate EV charging plug receptacles, and the EV charging plug receptacles are each connected to one or more of the communication connections and are each connected to one or more of the power connections.

In another embodiment, one of the charging protocol compliance signal generators comprises a pulse sequence generator.

In another embodiment, one of the charging protocol compliance signal generators comprises a pulse width modulator controllable by a system controller.

In another embodiment, one of the charging protocol compliance signal generators comprises a bidirectional communications interface.

In another embodiment, the charging protocol compliance signal generator having a bidirectional communications interface further comprises a switching sequence generator.

In another embodiment, one of the charging protocol compliance signal generators comprises a switching interface controllable by a system controller.

In another embodiment, the load module comprises a resistor.

In another embodiment, the load of the load module is a simulation of the load of an electric vehicle.

In another embodiment the EV charger compliance test system further comprises a signal monitoring sensor sensing electrical signals of one or more of the power connections and in communication with the system controller.

In another embodiment the EV charger compliance test system further comprises a plurality of terminal connectors, the terminal connectors being attachable to terminals of an EV charging plug to provide electrical connection between the EV charging plug, one or more of the communication connections, and one or more of the power connections.

In yet another embodiment, an electric vehicle (EV) simulation apparatus is provided, comprising a microprocessor connected to a communications interface, wherein the communications interface complies with an EV charging protocol, the microprocessor is connected to a memory means, which memory means contains EV charging protocol instructions executable by the microprocessor to cause the communications interface to provide signals to an EV charger in compliance with an EV charging protocol determined by the microprocessor.

In another embodiment, the memory means stores EV charging protocol instructions for two or more EV charging protocols, and the communications interface complies with each of the stored EV charging protocols.

In another embodiment, the EV simulation apparatus further comprises a user interface, and the user interface is connected to the microprocessor and permits selection of an EV charging protocol.

In another embodiment, the communications interface complies with two or more EV charging protocols.

In another embodiment, the communications interface comprises two or more EV communications simulators, which EV communications simulators each comply with an EV charging protocol.

In another embodiment, one of the EV communications simulators comprises a switching interface and a bidirectional communications interface.

In another embodiment, one of the EV communications simulators comprises a pulse sequence generator.

In another embodiment, the EV simulation apparatus further comprises a charge load absorber connected to a power interface, the power interface complies with an EV charging protocol, and the charge load absorber matches charge load absorption characteristics of an EV.

In some embodiments, a method of testing an electric vehicle (EV) charging apparatus using an EV charging tester is provided. This method comprises receiving an indication of a charging protocol used by an EV charging apparatus, providing a simulation signal to the EV charging apparatus, the signal simulating an EV acting in compliance with the charging protocol, and receiving a charge load from the EV charging apparatus with a load module.

In another embodiment, the EV charging tester provides a simulated EV status signal from a plurality of supported charging protocols.

In another embodiment, the indication is received by sensing properties of an EV charging plug connecting the EV charging apparatus and the EV charging tester.

In another embodiment, the indication is received as input from a user interface.

In another embodiment, the simulation signal is provided in part by a pulse sequence generator.

In another embodiment, the simulation signal is provided in part by a switching interface.

In another embodiment, the simulation signal is provided in part by a bidirectional communications interface.

In another embodiment, the method further comprises measuring an electrical property of the charge load using an electrical sensor.

In another embodiment, the method of claim further comprises comparing compliance of the electrical property with an EV charging specification and indicating a state of compliance at a user interface.

In another embodiment, the method further comprises comparing the electrical property to an EV charging specification, detecting noncompliance of the electrical property, and terminating the charge load as a result of detecting noncompliance of the electrical property.

In yet another embodiment a method of testing multiple electric vehicle (EV) charging protocols using a single EV charger testing system is provided. This method comprises determining a charging protocol to be tested by an EV charger testing system by sensing a charging station and configuring the EV charger testing system to comply with the determined charging protocol.

In another embodiment, the charging protocol to be tested is determined by sensing the presence of a charging plug in a charging plug receptacle, the charging plug being part of the charging station. In another embodiment, the presence of a charging plug is sensed in a charging plug receptacle by a sensor or switch.

In another embodiment, the EV charger testing system is configured by adjusting the resistance of a load module in the EV charger testing system.

In another embodiment, the EV charger testing system is configured by activating a communication connection between the EV charger testing system and the charging plug.

In yet another embodiment, a charger testing system for testing multiple electric vehicle (EV) charging protocols is provided. This charger testing system comprises an interface for receiving an indication of a charging protocol used by an EV charging apparatus, a signal provider for providing a simulated EV status signal to the EV charging apparatus in compliance with the charging protocol, and an EV load simulating means for receiving a charge load from the EV charging apparatus.

In another embodiment, the signal provider is capable of providing a plurality of supported charging protocols.

In another embodiment, the charger testing system further comprises a sensor or switch configured to send an indication of a charging protocol supported by a charging plug port.

In another embodiment, the signal provider is a signal generator comprises a bidirectional communications interface, a pulse sequence generator, and a switching interface.

In another embodiment, the charger testing system further comprises a specification verification means for determining compliance of the charge load with a specification of the charging protocol.

In at least some of these embodiments, repetitive and robust testing of EV charging stations is enabled as one or more charging protocols or standards can be tested, tests can be performed without the need for one or more actual EVs, testing times can be shortened, and testing failures or noncompliant charging stations can be more closely analyzed and have their problems more quickly diagnosed.

Additional and alternative features, advantages, and embodiments of the invention will be set forth in the description which follows, and in part will be obvious from the description, or may be learned by the practice of the invention. The features and advantages of the invention may be realized and obtained by means of the instruments, steps, and combinations particularly pointed out in the appended claims. These and other features of the present invention will become more fully apparent from the following description and appended claims, or may be learned by the practice of the invention as set forth hereinafter.

### BRIEF DESCRIPTION OF THE DRAWINGS

In addition to the novel features and advantages mentioned above, other objects and advantages of the present invention will be readily apparent from the following descriptions of the drawings and exemplary embodiments.

FIG. 1 is a modular block diagram of an embodiment of an electric vehicle (EV) charger testing system.

FIG. 2 is a high-level circuit block diagram of a charger compliance test system of an embodiment of the invention.

FIG. 3 is a lower-level circuit block diagram of the elements comprising an EV charging compliance test system supporting at least two charging protocols according to an embodiment of the invention.

FIG. 4 is a detailed view of a switching interface of an embodiment of the invention.

FIG. 5 is a flowchart showing exemplary embodiments of a method of using and controlling a charger testing system.

### DETAILED DESCRIPTION

The detailed description set forth below in connection with the appended drawings is intended as a description of the presently preferred embodiments of testing systems provided in accordance with aspects of the present invention and is not intended to represent the only forms in which the present invention may be constructed or utilized. The description sets forth the features and steps for making and using the test systems and methods of the present invention in connection with the illustrated embodiments. It is to be understood, however, that the same or equivalent functions and structures may be accomplished by different embodiments that are also intended to be encompassed within the spirit and scope of the invention.

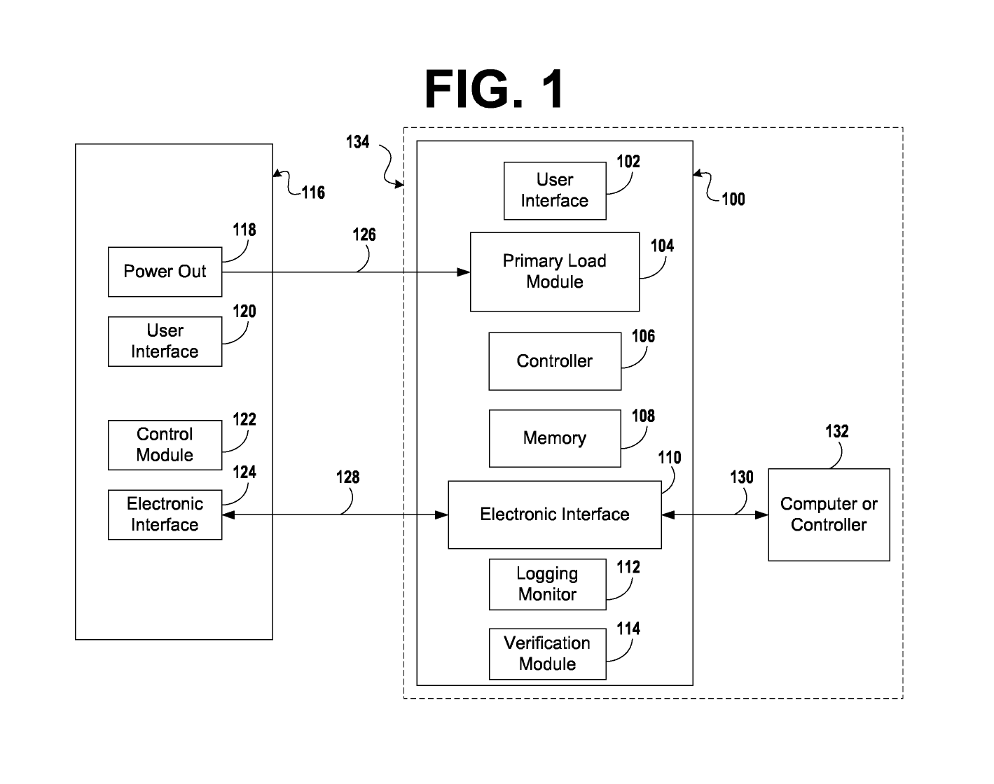

Referring now to FIG. 1, a modular block diagram of an embodiment of an electric vehicle (EV) charger testing system 100 is shown. In this embodiment, the charger testing system 100 is comprised of a user interface 102, a primary load module 104, a controller 106, electronic memory 108, an electronic interface module 110, a logging monitor 112, and a verification module 114. The charger test system 100 is shown in communication with an electric vehicle charging station 116 having a power out 118, user interface 120, control module 122, and electronic interface 124. The power out 118 provides power to the primary load module 104 via a power line 126, and the electronic interface 124 is in communication with the electronic interface module 110 via a communication line 128. In some related embodiments, the electronic interface module 110 is also connected via another communication line 130 to a computer or external controller 132. In yet other embodiments, the computer or controller 132 is integrated as part of the charger testing system 100, as indicated by box 134.

The user interface 102 of the charger testing system 100 is comprised of displays, output devices, indicators, gauges, input devices, buttons, dials, and other related components for receiving and providing data between a user and the charger testing system 100. In some embodiments, the user interface comprises a keyboard for input and an electric monitor or other display device for output of information. The user interface 102 is connected to the controller 106, as the controller receives and interprets the inputs and produces the signals sent to the output devices that are part of the user interface 102. An exemplary user interface module provides a keyboard and data terminal that allows the user to access key control and data parameters and enables the user to execute commands including initiate, start, stop, emergency stop, and display. The user interface module may also be configured to provide lights, sounds and other alerts regarding the state of charging.

The primary load module 104 of the charger testing system 100 acts as an electrical energy absorbing element for the system. One of its functions is to receive and absorb power output from the charging station 116. For example, absorbing the power may be completed by dissipating the energy as heat in a resistor or storing the energy in an energy storage system such as a capacitor or battery. In some embodiments it is advantageous to use a resistive element in the primary load module 104 in order to allow more frequent testing of the charging station 116 without a need to discharge an energy storage means in some fashion. However, an energy storage means may be preferable in cases where energy conservation is important since the energy of the energy storage means may be reused for other purposes, including acting as an energy source for the rest of the charger testing system 100. Therefore, embodiments having resistive and energy storage components may be advantageous in both situations.

In some embodiments, the primary load module 104 is designed in such a manner that it imitates the load of an electric vehicle. In accordance with EV charging protocols, EV charging stations provide energy to EVs at different rates and power levels based on a number of factors, including the state of charge of the EV's energy storage device, the available power for the charging system, the state of communication between the EV and the charging station, and more. A primary load module 104 may therefore be advantageous to the user when it is able to simulate various states of charge, resistance levels, and other conditions that vary when EVs are charged by a charging station. For example, this capability may be advantageous when the charging station is improperly ending charging events for EVs too early. With a resistive element that can be controlled to simulate the resistance of a nearly-charged EV battery system, the charger testing system 100 can be used to repeatedly receive energy from the EV charging station 116 as if multiple nearly-charged EVs were being connected to the charging station 116 in close succession, and the user may observe the inconsistencies or errors in the behavior of the charging station 116 more readily than having to wait for multiple depleted EVs to be nearly fully charged, for instance. A variable load module 104 also allows the user to simulate unexpected behaviors such as faulty EV batteries or inverter systems that might not be possible using EVs to test the charger 116 without damaging the EVs. The resistance and/or other load properties of the primary load module 104 may be static or dynamically controlled by a controller (e.g. controller 106). Dynamic control while receiving power from the charging station 116 may be advantageous since these properties change in many EVs while they are charged. Therefore, the primary load module 104 may more accurately and completely simulate and virtualize an EV when it is connected to and receiving power from a charging station 116. The load module 104 may also have the capability of being removable and replaceable with a different load module so that multiple load modules may be used to simulate the load of different types and models of vehicles, when appropriate.

In some embodiments, the primary load module 104 may be comprised of multiple load modules. Multiple load modules may be connected and disconnected in patterns or sequences to imitate the load of an electric vehicle. They may also be used separately and independently based on the charging protocol being tested. For example, a high-power charging protocol could use one designated primary load module or one part of a primary load module, while a lower-power charging protocol could be tested using a different primary load module or different part or configuration of a primary load module. In some embodiments, the load module 104 provides the testing system the ability to absorb difference charge rates from an EV charger as if it were a battery taking on charge. With the load module 104 as a resistive element, energy absorbed can be released as heat in a safe and transparent manner. Such a load module can be controlled by a bank of power switches controlled by opto-isolated connections to the control module. Test parameters are then measured at the input of the load module where they are easily accessed using measuring devices such as resistive divide circuits and hall sensors. Alternatively, external sensors may be used so that these measurements are made on the DC load wires entering the testing system.

A controller 106 is provided in this embodiment to manage, monitor, and report on the operation of other components of the charger testing system 100. For example, the controller 106 may be used to control the primary load module 104 in order to simulate an EV while power is being received from the charging station 116. Furthermore, the controller 106 may be used to interpret user input, execute instructions, and provide information to the user interface 102, logging monitor 112, verification module 114, memory 108, and electronic interface module 110, and to perform other related functions. In this case, the controller 106 may use sensors such as current, voltage, or temperature transducers as a source of information. The controller 106 can be advantageously embodied as a microprocessor, hardware logic controller, general purpose computer, or other control device capable of completing testing procedures. Preferably, the test system controller 106 comprises a digital reprogrammable controller containing memory and control logic sufficient to encompass the requirements for a wide variety of charger testing. This allows the controller to profile specific charge loads and to execute specific charge load profiles in a charging process for testing purposes. An external computer or controller 132 may be used to send and receive instructions to and from the testing system 100, such as updating or adding to charging protocols stored by the memory 108 or receiving alerts of faults in the tester operation received by the electronic interface module 110. Such an external computer 132 may be connected through a serial interface for bidirectional communication.

The memory 108 is connected to the controller 106 as a source of temporary and/or permanent data storage. For example, the memory 108 may store charging protocol parameters that are compared to the load experienced by the primary load module 104 for charging protocol compliance verification, or the memory 108 may be used as a source of data storage for sensor measurements received by the controller 106. Any electronic memory means known in the art may be used as memory 108 in the charger testing system 100, including, for instance, a hard drive, compact disk (CD), DVD, RAM, ROM, or other non-transitory computer-readable medium.

The electronic interface module 110 interfaces with the electronic interface 124 of the charging station 128. In some embodiments the electronic interface module 110 comprises one or more communication interfaces and/or signal generators that are enabled to provide verification signals in compliance with the charging protocol being tested by the charger testing system 100. For example, if a first charging protocol requires a signal generator to provide a pilot signal indicating the status of an EV before the EV charging station outputs power through the power line 126, the electronic interface module 110 is a pilot signal generator controlled by the controller 106 or an external control means 132 that outputs the required signal to cause the charging station to provide power as if it was providing power to an EV. The electronic interface module 110 may also be a bidirectional communications interface (as indicated by the bidirectional arrow of the communication channel 128, where information is exchanged between the charger testing system 100 and the charger 116 such as the electronic interface module 110 sending status information to the charger and the charger 116 sending fault information or other information about the state of charging or the state of the charger 116 to the electronic interface module 110. In some embodiments, multiple communication lines 128 are implemented between the testing system 100 and the charging station 116, such as when the charging protocol being tested requires multiple simultaneous lines of communication. For example, because some charging protocols require an electronic switching interface and a bidirectional communications interface to simultaneously send and receive information, multiple communication lines 128 may be used to support those protocols. Supporting many existing charging protocols may require that up to eighteen (18) different lines may be established as communication lines 128 and power lines 126 to exchange signals and to receive energy from the charging station 116. In some embodiments the electronic interface module 110 is a vehicle communications system including but not limited to vehicle to vehicle (V2V), Wireless Access in Vehicular Environments (WAVE), On Board Units (OBU), On Board Diagnostics (OBD), Ethernet, Power Over Ethernet (POE), RS232, RS485, Control Access Networks (CAN), and other comparable and future communications protocols. Some protocols require a “handshaking” of signals between a vehicle and the charging station, such as TEPCO® CHAdeMO®, where a switching interface is used by the vehicle to verify that the vehicle is properly connected to the charging station, is ready to receive a charge, or other confirmation signals are exchanged. In these embodiments, the electronic interface module 110 also includes the switching interface that allows the charging station to provide energy to the testing system as if the testing system was a properly connected EV. Existing EV charging protocols that may be supported by electronic interface modules of embodiments of the invention include SAE J1772, IEC 62196, and CHAdeMO®. The electronic interface module 110 provides the appropriate physical interface for these communication standards when they are implemented as part of the testing system 100. In some embodiments, a bidirectional communications interface is included, but is used as if it were a one-way communication interface for complying with charging protocols that do not require information exchange back and forth between an EV (or charger testing system) and the charging station.

In some embodiments a logging monitor 112 provides the functionality of logging and recording the EV charge sequence and power levels received from the charger 116 by the testing system 100 for later debug and analysis. In some embodiments, real-time debug and analysis is provided via the user interface displaying charge parameters to a user. The logging monitor 112 may be incorporated as part of the controller 106 or may be a separate or independent component of the system 100 used for logging purposes. If the logging monitor 112 is held separate from the controller 106, an extra source of data for verification of compliance with a charging protocol may be provided.

In some embodiments a verification module 114 is provided that compares the charging protocol specifications to the output of the charger 116 and reports or stores a verification of whether the specifications are being properly followed in the charger 116. A verification module 114 contains active digital circuits which record the activity under test such as stat of the charge sequence, sequence of events, voltage, amperage, temperature, and the communication sequence of the charger. The verification module 114 compares this data to accepted performance data within internal memory to ensure that the EV charge is working within an accepted performance envelope that is required by EV charging standards. The functions of the verification module 114 may also be incorporated in the operation of the controller 106.

The power connections (or power lines) 126 link the power output 118 of the charging station 116 to the testing system's primary load module 104. The connection between these parts may advantageously position the power connections 126 within a charging cable that connects the system 100 and the station 116. Typically, the communication lines or connections 128 are also within the charging cable, but they may also be connected separately when appropriate. For example, a single power carrying charging cable may be used with multiple charging protocols, but different communications cables may be used for each different protocol. In many cases, each protocol will have a different charging cable specification, so multiple charging cables are used, each containing power lines and communication lines appropriate for the different protocols. For support of the CHAdeMO or J1772 protocol, two male power connectors provide DC power input to a vehicle, so the primary load module would be connected to an EV charger connection interface having two power connections to receive the power from the male power connectors. The EV charger connection interface would provide connections with protocol-compliant power ratings, sizes, and shapes to accommodate each supported protocol. Communication connections 128 or 130 may be established through wired or wireless means to provide flexibility for the user in completing the connections 128 or 130 in compliance with the established protocols. In some embodiments, such as embodiments designed to be configured to connect to future charging protocols, a set of terminal clips or screws or other grasping or fastening connectors may be provided as part of the power connections 126 and communication connections 128 to connect to terminals of EV charging standards that have not yet been implemented. Such connectors may be advantageously sized and designed to be attached to a bare wire within a charger cable for cases where power-carrying lines are inaccessible at a charger's connector.

An EV charger connection interface in these embodiments comprises a number of communication connections or lines used for communication of information to and/or from an EV and an EV charger. For example, an EV charger connection interface may comprise communication connections through which a CAN interface is conducted and additional communication connections through which a number of digital switches provide “handshaking” signals prior to the provision of charge by a charger. In some embodiments, these communication connections are established wirelessly such as through Zigbee®, Bluetooth®, Wi-Fi, or other similar wireless communication protocols. Some currently used protocols require one communication connection line between an EV and the EV charger, but any higher number of connections may be supported by the charger testing system in order to comply with charging protocols requiring a higher number of these connections. Additionally, the EV charger connection interface comprises a number of power connections or lines used for transmission of power between the EV charger and the charger testing system. In some embodiments these power connections mimic the power connections found in a charging plug receptacle on an EV in their shape, size, number, and positioning in order to accurately test the output of the EV charger as if it were connected to an EV. A number of currently used protocols require two power connection lines between an EV and the EV charger, but any higher number of connections may be supported by the charger testing system in order to comply with charging protocols requiring a higher number of these connections. “Compliance” of communication or power connections with a charging protocol means that the communication or power connections are properly sized, shaped, positioned, and otherwise designed to meet minimum requirements for connection of the EV charger testing system to an EV charger and establishing that, to the EV charger, the EV charger testing system correctly mimics the function of an EV when connected to the EV charger to an extent that the charger is able to output charge in compliance with the charging protocol that the connections comply with.

In some embodiments, the EV charger connection interface comprises one charging plug receptacle which supports one or more charging protocols. For example, such a charging plug receptacle may have different pins that are accepted by charging plugs of multiple protocols that have different shapes. A single charging plug receptacle may also support more than one charging protocol without hardware differences between the charging protocols, in which case communication between the charger and the testing system or input of a user determines which charging protocol is to be tested. In yet other embodiments, the EV charger connection interface comprises two or more charging plug receptacles, and each receptacle supports one or more different charging protocols. Here, the charging protocol tested by the testing system may be determined by sensors detecting where a connecting plug is inserted, which plug is inserted into the ports first, or another comparable process.

In some embodiments, the charging protocol is determined by sensing a portion of the charging plug inserted into a receptacle, such as when a flange or pin presses a button or triggers a switch that is part of the charger testing system, and wherein the flange or pin pressing the button or triggering the switch establishes the identity of the charging protocol that will be used by the plug. For example, if a flange is only used in one charging protocol, a switch depressed by a flange unique to that charging protocol may be triggered to permit the charger testing system to configure itself for that kind of charging. In another example, a switch may be depressed at the base of a charging plug receptacle that indicates that a charging plug complying with a certain protocol has been inserted into the plug, so the charger testing system prepares itself to test that protocol. The configuration of the EV charger testing system may be completed by adjusting the resistance of the load module of the system or by activating a communication connection such as a bidirectional communications interface or sending a signal to the EV charger created by a pulse width modulator and disabling a bidirectional communications interface.

The charger testing system 100 may be used to provide functionality such as acquiring availability of the EV charger's charge parameters, including but not limited to standard/protocol compliance, voltage, amperage, capacity, temperature, and rate of charge or power level. With a variable and/or controllable load module, it gives the capability to profile various charge scenarios for a variety of loads from mild charges to completely depleted battery systems. It may also provide ability to monitor safety items including but not limited to ground faults, voltage faults, over voltage, over amperage, over temperature, and incorrect charge rates or other malfunction in the EV charger. A controller of the charger testing system may provide ability to disable or restart the charge sequence of the EV charger or to alert a technician or other user of charge conditions or data collected. These capabilities provided by embodiments of a charger testing system are beneficial to a user in ways that existing methods and apparatuses do not provide.

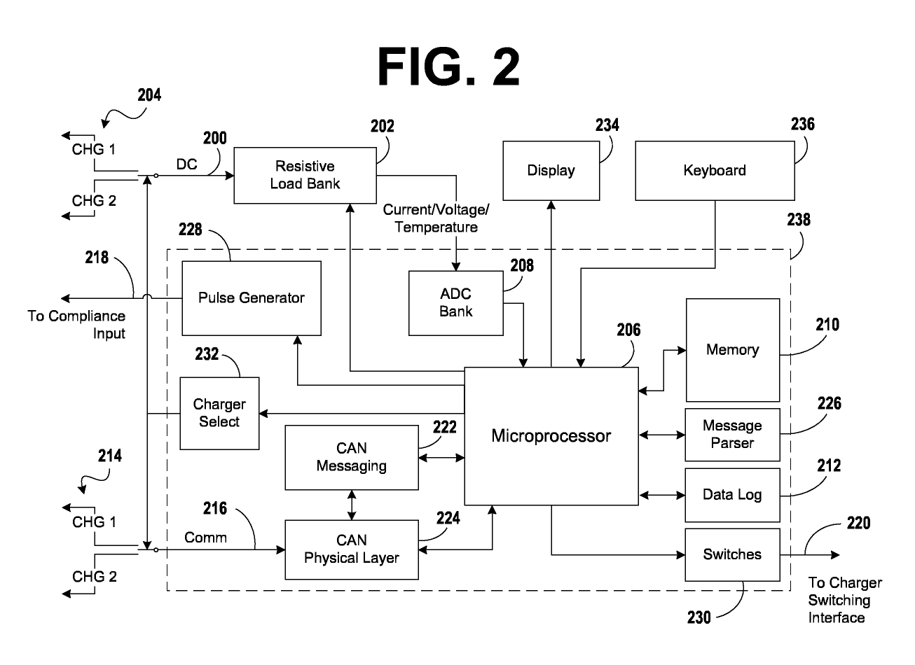

Referring now to FIG. 2, a high-level circuit block diagram of a charger compliance test system of an embodiment of the invention is shown. A power connection 200 comprising a line capable of carrying protocol-compliant power levels, such as a pair of DC power lines, is connected to a resistive load bank 202 and to an EV charger connection power connection interface 204. Current, voltage, and/or temperature measurements are taken and converted for reading at a microprocessor 206 by an analog/digital conversion and digital/analog conversion bank 208. The microprocessor 206 acts as a central control and processing unit, executing instructions stored in memory 210, storing charge compliance data and other instrument readings in a data log 212, and controlling the exchange of information to and/or from an EV charger connection communication connection interface 214 via a communication connection 216, 218, and/or 220. In this embodiment, communication line 216 is supports CAN, a bidirectional communications interface for exchanging information between the EV charger and the testing system, and the CAN interface comprises a messaging module 222 and a physical layer 224 for sending and receiving information between the charger and the testing system. A message parser 226 is also provided in communication with the microprocessor that allows lexical management of the data interface present. In this case, the data interface is CAN, but the message parser may also be implemented to serve its function for Modbus, Ethernet, PLC, and the other communication interfaces used by vehicle chargers.

Depending on the charging protocol being tested, the testing system of FIG. 2 may use one or more communication connection 216, 218, or 220. For example, if SAE J1772 or a comparable standard of charging is being tested, a pulse generator 228 is controlled to provide a pulse train or pilot signal to an input of the charging station that is used to determine readiness of an EV and compliance with the J1772 protocol. In some embodiments the pulse generator 228 of this embodiment comprises a pulse width generator. If CHAdeMO or a comparable standard of charging is being tested, a switching interface on the charger receives switching signals from a series of switches 230 that comprise a switching interface for the charger tester that imitates and simulates the switching of an EV that is compliant with CHAdeMO. In some embodiments the total number of switches 230 is at least twenty four (24) and enable pull-high, pull-low, or open collector style interaction via a network of isolated electric circuits within the charger testing system. Having twenty four switches allows a charging system to interact with existing EV charger systems and have additional spare units to interact with future EV charger protocols.

The microprocessor 206 is also configured to make a charger selection in the charger testing system when multiple charging protocols or chargers are usable. In the embodiment shown in FIG. 2, the charger selection module 232 determines whether one charger or a second charger is connected to the charger testing system via the power connections 200 and/or the communication connections 216. A charger selection module 232 may be an embedded logic circuit or a microprocessor-executed software program that determines which switches in the EV charger connection interfaces 204 and 214 will be closed. In other embodiments, the charger selection module 232 receives signals from the EV charger connection interfaces 204 and 214 in order to determine which switches are closed. For example, in some embodiments the EV charger connection interface is a number of charging plug receptacles, and when a charging plug connector is inserted into one of the receptacles, a signal is received by the charger selection module 232 that indicates that it should close the switches that are compliant with the inserted charging plug connector's charging protocol. Alternately, the indication of which charging protocol to use can come from a separate communications interface, user input via an input device such as the keyboard 236, past settings of the charger testing system, or sensors measuring the electrical or physical status of the EV charger connection interface receptacles. For example, in some embodiments, there is only one charging connector receptacle in the EV charger connection interface, so a user inputs the type of charging protocol testing desired, and the charger selection module 232 closes the appropriate switches. In another example, the shapes or electrical properties of the charging connector inserted into the charging connector receptacle are sensed, and this data indicates the charging protocol that will be tested.

A user interface for the charging tester system is provided by a display 234 for output of information to a user and keyboard 236 for input and control from the user. The dashed-line box 238 indicates an embodiment of the invention where the components shown within the box are all part of a single printed circuit board (PCB).

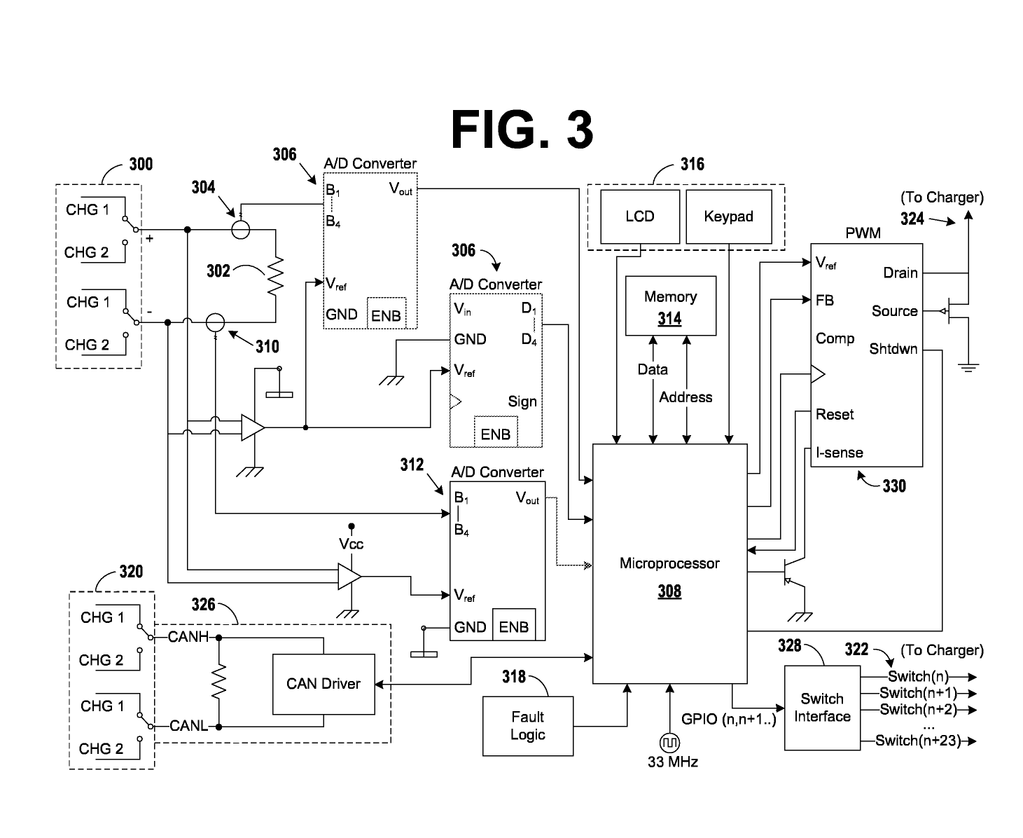

FIG. 3 is a lower-level circuit block diagram of the elements comprising an EV charging compliance test system supporting at least two charging protocols. Power connections 300 of an EV charger connection interface are connected to a resistive element 302 which simulates the load of an EV connected to the EV charger. Current is measured going into the resistive element 302 with a current transducer 304 and Analog/Digital (A/D) converters 306 that provide the readings to a microprocessor 308. This allows the testing system to measure current ripple on the input from the charger and provide data on the ripple performance of the charger, a measure which directly affects battery lifespan. Current is also measured leaving the resistive loop by a current transducer 310 providing a reading to an Analog/Digital (A/D) converter 312 that provides the reading to the microprocessor 308. These current measurement devices assist in enabling the testing system to monitor power levels coming from the EV charger and to detect current leakages or other faults in the power provided to the charger testing system. The microprocessor 308 exchanges data with a memory/electronic data storage medium 314 and has a user interface 316. Fault logic 318 is a software or firmware (or a combination of both) portion of the system that detects and alerts faults in the charging station or the power or signals being provided by the charging station. In some embodiments a digital/analog converter is provided to receive a signal from a temperature transducer and feed a converted signal to an analog input on the microprocessor.

Communications connections between a charging station and the charger testing system are based on the nature of the protocol or protocols supported by the testing system. In this embodiment, an EV charger connection interface has CAN communication connections 320, a switching interface connection 322, and a pulse train generator connection 324. The CAN communication connections 320 link a CAN interface 326 in the testing system to a CAN interface in the EV charger, the switching interface connections 322 link the testing system to a charger supporting a protocol such as CHAdeMO through a switch interface 328 connected to general purpose I/O (GPIO) pins of the microprocessor 308, and the pulse train generator connection 324 links a pulse width modulator 330 under control of the microprocessor 308 to the charger supporting a protocol such as SAE J1772 which uses a pilot signal or voltage drop to recognize the compliance of an electric vehicle.

In an exemplary embodiment, the charger testing system provides pulse width modulation control via general purpose output of the microcontroller. This general purpose I/O signal is modulated with software control to provide interface control which may be a 1 kHz signal as needed by the SAE J1772 Pilot control signal. Additionally the microprocessor may provide power selection to fixed bridge control electronics such that its duty cycle corresponds to the percentage of total output power created by such bridge mechanism.

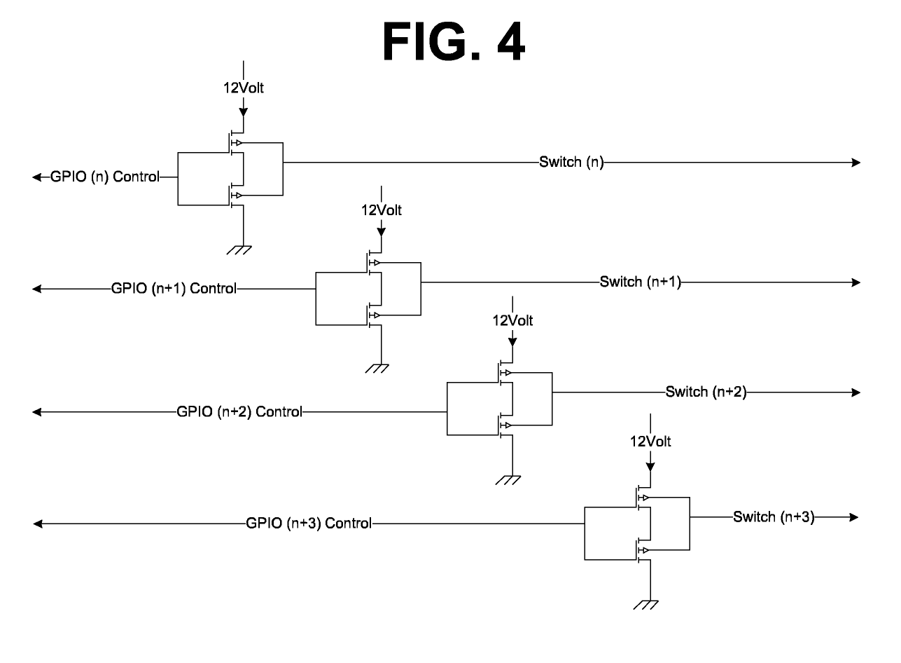

FIG. 4 shows detail of a switching interface such as switching interface 328 of FIG. 3. Control connections shown on the left are linked to GPIO pins of the microprocessor and switch outputs shown on the right are directed to appropriate switching communication connections of the EV charger. This series of switching circuits (for example, up to twenty-four in this case) enables a testing system to complete the “handshaking” normally performed between a protocol-compatible EV and the EV charger. For protocols using a switching interface of this type, it would not be possible to receive charge and test the charging station without simulating these signals using this switching interface. The twenty-four circuits in this embodiment are required for compatibility with CHAdeMO and related protocols with switching verification sequences.

Embodiments of a charger testing system such as those disclosed herein may follow predefined testing procedures. In one exemplary embodiment, testing procedures are part of a program stored by memory and executed by a microprocessor. This allows a charger testing system to repeatedly test a charging station under consistent operating conditions without introduction of human error. Furthermore, because of the nature of some EV charging protocols, EV charging stations react to certain signals and behaviors from the device to which they are connected, which is normally an EV. Thus in order to properly simulate a connection between the EV charging station and an EV, the charger testing system must be able to perform steps which replicate the sequence of signals and/or exchanges of information provided by an EV to an EV charging station according to each protocol supported by the charger testing system.

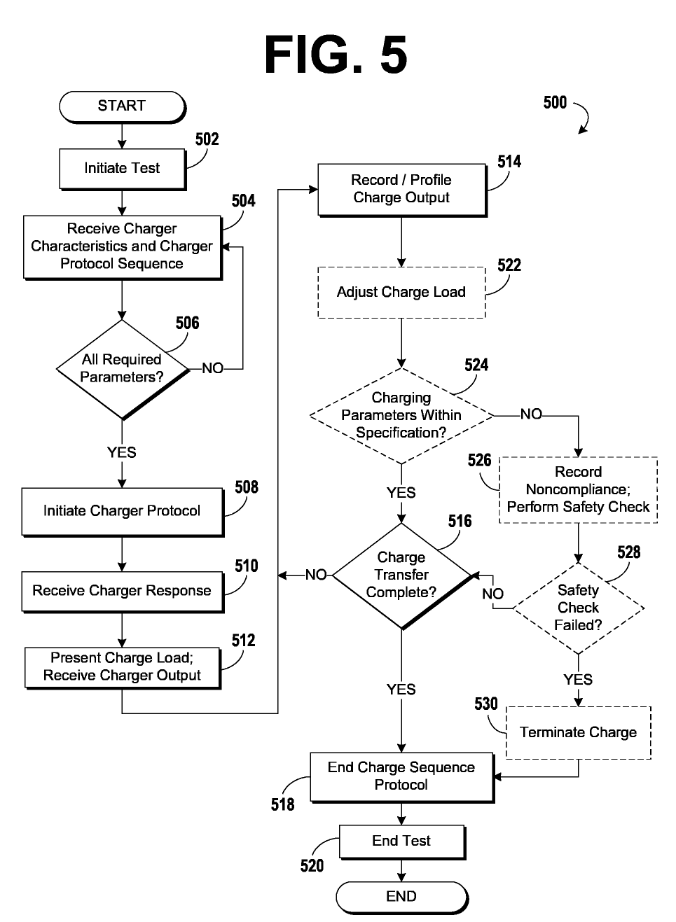

FIG. 5 is a flowchart showing exemplary embodiments of a method of using a charger testing system. The testing method 500 begins with initiation of a test at step 502. This comprises starting up the EV charging station and charger testing system and establishing the power and communications connections necessary for a charge transfer to take place between them. Next, at step 504, a controller of the charger testing system receives charger characteristics and the charger protocol sequence, and continues to do so until all required parameters are gathered in step 506. In some embodiments the charger characteristics received in step 504 include charger identification information such as a serial number, EV charging protocols supported by the charging station, the status of the charging station, available power for charging, charging scheduling constraints, faults and error messages, charge rate requirements for voltage and current, safety checks such as leakage and ground checks, or the propriety of the connection between the charger and the charger testing system. Charger characteristics may be ascertained through the connection to the EV charging station, or may be supplied to the charger testing system through a user input device. In some embodiments, a memory device in the charger testing system stores a profile of a charging station and uses that information in supplement to any input characteristics or identifying information from a user or received via the communication connection to the charging station.

A charger protocol sequence is a sequence of signals or events or instructions that are specific to a charging protocol or specification being used by the charging station. It defines the steps that need to be taken for a charge transfer to be completed between an EV and the charging station to which it is connected. For a charging protocol such as SAE J1772, the protocol sequence is a pulse train sequence or other signal that indicates that a vehicle is attached, but according to other protocols the sequence may contain more information such as a switching sequence sent to the charger along with another signal. In some embodiments this charger protocol sequence is not communicated independent from the charger characteristics, and it is received as part of information comprised in the characteristics of the charger or it is stored by memory of the charging tester.

The testing system initiates the charger protocol in step 508. In some embodiments this means the controller of the charger testing system, which is embodied as a state machine, parses the charge characteristics and protocol sequence, checks to see if they are within charger specifications or fall within another appropriate range, and initiates the charge procedure by sending charge parameters, charge characteristics, and a request to begin charging to the charger. The protocol-specific signal and switch sequences which mimic an EV may also be provided to the charger.

The charger testing system may then receive a charger response in step 510, if the protocol being tested has such a step, and the charger testing system supplies the appropriate load as if it were an EV prepared to receive charge in step 512. In presenting the charge load, the controller of the charger testing system may be required in some embodiments to adjust the settings of a charge load module, such as changing the electrical characteristics (e.g., resistance or impedance) of the load module, to mimic the characteristics of an EV that would be charged under the charge parameters that are to be tested by the testing system. The charging station then provides charge output to the load module and the testing system records or profiles the charge output in step 514 as it is provided. This recording or profiling may be performed continuously, at regular intervals, or intermittently depending on the nature of the charging protocol being tested, the behavior of the EV charger as it provides charge, or user preference. Recording and profiling may be done by sensing measurements of current, voltage, power, temperature, rate of change of these properties, or other relevant charging characteristics and then storing the measurements in a data storage medium such as a hard disk or memory device, displaying the measurements on a display or other output device, or transmitting the measurements to an external computer for analysis or storage.

In some embodiments, the testing system then waits for the charge transfer to be completed, as shown in step 516, ends the charge sequence protocol in step 518, then ends the test in step 520. In other embodiments, one or more routines may be performed while charge is being provided to the testing system. For example, in some embodiments the charge load is adjusted while the charge is being provided, as shown in step 522, so the testing system monitors the charge output and changes the load module's properties in response. In some cases this means that the resistance of the load module is controlled and changed over time to mimic the change in resistance of the battery system of an EV that is being charged. In other embodiments, the load module's properties are changed in order to test the fault detection or other sensors of the charging station, such as in a testing simulation where a ground fault occurs during a charging event or there is a sudden change in battery resistance. The adjustment of charge load while charger output is received enables the testing system to more accurately imitate the load of an EV, such as an EV that has its resistance increase as the temperature of the battery system increases during charging. It also provides improvement over a static resistor bank or a resistor bank that is changed only before charge is received in the capability of the system to simulate a wider range of potential failure modes.

In another exemplary embodiment, the charging parameters monitored and recorded in step 514 are compared to expected specification values in step 524. For example, this may mean that the testing system determines whether the current or voltage supplied to the load module falls within a range of acceptable values defined by the specification of the charging protocol being tested. If the measurements are within specification, the testing system continues with the charge transfer at step 516. If the measurements are not within specification, noncompliance of the charger is recorded and a secondary safety check is performed at step 526. For example, anomalous leakage current, false readings, over-temperature readings, error messages, inadvertent opening of a switch, or other noncompliant actions are recorded and a safety check of the data received is completed. In some embodiments, a safety check is not performed in step 526, and the process resumes at step 516 after noncompliance of the charge output is recorded.

The safety check is a determination of whether the noncompliance of the charger determined in step 524 is dangerous, such as a charge output that may damage an EV, damage the charger testing system, or harm a user or other nearby person. If the safety check fails, the charge output from the charger is terminated in step 530 as a cutoff signal is sent to the charger or an alert is sent to a user to disable, adjust, or disconnect the charger. Afterward, the process resumes at step 518 or step 520. When the safety check is does not fail in step 528, the process resumes at step 516 without terminating the charge output from the charger.

Steps 524-530 relating to safety and compliance-comparisons provide to the user an ability to monitor how and when the charger is providing charge that is outside the specified bounds of the charging protocol while keeping equipment and users protected from dangerous conditions. By using a charger testing system instead of a real EV, risk of damage to expensive equipment can be limited to the price of the components of the charger testing system, and specifications can be adjusted or updated as the user sees fit, whereas many existing EVs do not allow charging outside of their preloaded specifications and protocols. Thus, charging stations can be subjected to more rigorous and thorough testing than can be provided by EVs alone, yet capital outlays are limited.

Some methods and systems of the embodiments of the invention disclosed herein may also be embodied as a computer-readable medium containing instructions to complete those methods or implement those systems. The term “computer-readable medium” as used herein includes not only a single physical medium or single type of medium, but also a combination of one or more tangible physical media and/or types of media. Examples of a computer-readable medium include, but are not limited to, one or more memory chips, hard drives, optical discs (such as CDs or DVDs), magnetic discs, and magnetic tape drives. A computer-readable medium may be considered part of a larger device or it may be itself removable from the device. For example, a commonly-used computer-readable medium is a universal serial bus (USB) memory stick that interfaces with a USB port of a device. A computer-readable medium may store computer-readable instructions (e.g. software) and/or computer-readable data (i.e., information that may or may not be executable). In the present example, a computer-readable medium (such as memory) may be included to store instructions for the testing system to perform testing procedures or to act as a memory means for storing various charging protocols.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

In addition, it should be understood that the figures described above, which highlight the functionality and advantages of the present invention, are presented for example purposes only and not for limitation. The exemplary architecture of the present invention is sufficiently flexible and configurable, such that it may be utilized in ways other than that shown in the figures. It will be apparent to one of skill in the art how alternative functional, logical or physical partitioning, and configurations can be implemented to implement the desired features of the present invention. Also, a multitude of different constituent module or step names other than those depicted herein can be applied to the various partitions. Additionally, with regard to flow diagrams, operational descriptions and method claims, the order in which the steps are presented herein shall not mandate that various embodiments be implemented to perform the recited functionality in the same order unless the context dictates otherwise.

Although the invention is described above in multiple various exemplary embodiments and implementations, it should be understood that the various features, aspects and functionality described in one or more of the individual embodiments are not limited in their applicability to the particular embodiment with which they are described, but instead can be applied, alone or in various combinations, to one or more of the other embodiments of the invention, whether or not such embodiments are described and whether or not such features are presented as being a part of a described embodiment. Thus, the breadth and scope of the present invention should not be limited by any of the above-described exemplary embodiments. The invention is also defined in the following claims.

Terms and phrases used in this document, and variations thereof, unless otherwise expressly stated, should be construed as open ended as opposed to limiting. As examples of the foregoing: the term “including” should be read as meaning “including, without limitation” or the like; the term “example” is used to provide exemplary instances of the item in discussion, not an exhaustive or limiting list thereof; the terms “a” or “an” should be read as meaning “at least one,” “one or more” or the like; and adjectives such as “typical,” “conventional,” “traditional,” “normal,” “standard,” “known” and terms of similar meaning should not be construed as limiting the time described to a given time period or to an item available as of a given time, but instead should be read to encompass conventional, traditional, normal, or standard technologies that may be available or known now or at any time in the future. Likewise, where this document refers to technologies that would be apparent or known to one of ordinary skill in the art, such technologies encompass those apparent or known to the skilled artisan now or at any time in the future.

A group of items linked with the conjunction “and” should not be read as requiring that each and every one of those items be present in the grouping, but rather should be read as “and/or” unless expressly stated or context dictates otherwise. Similarly, a group of items linked with the conjunction “or” should not be read as requiring mutual exclusivity among that group, but rather should also be read as “and/or” unless expressly stated or context dictates otherwise. Furthermore, although items, elements or component of the invention may be described or claimed in the singular, the plural is contemplated to be within the scope thereof unless limitation to the singular is explicitly stated. The presence of broadening words and phrases such as “one or more,” “at least,” “but not limited to” or other like phrases in some instances shall not be read to mean that the narrower case is intended or required in instances where such broadening phrases may be absent.

Additionally, the various embodiments set forth herein are described in terms of exemplary block diagrams and other illustrations. As will become apparent to one of ordinary skill in the art after reading this document, the illustrated embodiments and their various alternatives can be implemented without confinement to the illustrated examples. For example, block diagrams and their accompanying description should not be construed as mandating a particular architecture or configuration.

Further, the purpose of the Abstract is to enable the U.S. Patent and Trademark Office and the public generally, and especially the scientists, engineers, and practitioners in the art who are not familiar with patent or legal terms or phraseology to determine quickly from a cursory inspection the nature and essence of the technical disclosure of the application. The Abstract is not intended to be limiting as to the scope of the present invention in any way.

What is claimed is:

1. An electric vehicle (EV) charger compliance test system, comprising:
an EV charger connection interface having one or more communication connections and one or more power connections, wherein one or more of the communication connections and one or more of the power connections comply with a first EV charging protocol, and wherein one or more of the communication connections and one or more of the power connections comply with a second EV charging protocol;
a load module connected to the power connections;
a first charging protocol compliance signal generator connected to one or more of the communication connections in compliance with the first EV charging protocol; and
a second charging protocol compliance signal generator connected to one or more of the communication connections in compliance with the second EV charging protocol.

2. The EV charger compliance test system of claim 1, wherein the EV charger connection interface supports two different EV charging plugs, and the EV charging plugs are compliant with different EV charging protocols.

3. The EV charger compliance test system of claim 1, wherein the EV charger connection interface comprises two separate EV charging plug receptacles, and wherein the EV charging plug receptacles are each connected to one or more of the communication connections and are each connected to one or more of the power connections.

4. The EV charger compliance test system of claim 1, wherein one of the charging protocol compliance signal generators comprises a pulse sequence generator.

5. The EV charger compliance test system of claim 1, wherein one of the charging protocol compliance signal generators comprises a pulse width modulator controllable by a system controller.

6. The EV charger compliance test system of claim 1, wherein one of the charging protocol compliance signal generators comprises a bidirectional communications interface.

7. The EV charger compliance test system of claim 6, wherein the charging protocol compliance signal generator having a bidirectional communications interface further comprises a switching sequence generator.

8. The EV charger compliance test system of claim 1, wherein one of the charging protocol compliance signal generators comprises a switching interface controllable by a system controller.

9. The EV charger compliance test system of claim 1, wherein the load module comprises a resistor.

10. The EV charger compliance test system of claim 1, wherein the load of the load module is a simulation of the load of an electric vehicle.

11. The EV charger compliance test system of claim 1, further comprising:
a signal monitoring sensor sensing electrical signals of one or more of the power connections and in communication with the system controller.

12. The EV charger compliance test system of claim 1, further comprising:
a plurality of terminal connectors, the terminal connectors being attachable to terminals of an EV charging plug to provide electrical connection between the EV charging plug, one or more of the communication connections, and one or more of the power connections.

13. An electric vehicle (EV) simulation apparatus, comprising:
a microprocessor connected to a communications interface, the communications interface complying with an EV charging protocol, the microprocessor being connected to a memory means, the memory means containing EV charging protocol instructions executable by the microprocessor to cause the communications interface to provide signals to an EV charger in compliance with an EV charging protocol determined by the microprocessor.

14. The EV simulation apparatus of claim 13, wherein the memory means stores EV charging protocol instructions for two or more EV charging protocols, wherein the communications interface complies with each of the stored EV charging protocols.

15. The EV simulation apparatus of claim 14, further comprising a user interface, the user interface connected to the microprocessor and permitting selection of an EV charging protocol.

16. The EV simulation apparatus of claim 13, wherein the communications interface complies with two or more EV charging protocols.

17. The EV simulation apparatus of claim 13, wherein the communications interface comprises two or more EV communications simulators, the EV communications simulators each complying with an EV charging protocol.

18. The EV simulation apparatus of claim 17, wherein one of the EV communications simulators comprises a switching interface and a bidirectional communications interface.

19. The EV simulation apparatus of claim 17, wherein one of the EV communications simulators comprises a pulse sequence generator.

20. The EV simulation apparatus of claim 13, further comprising:
a charge load absorber connected to a power interface, the power interface complying with an EV charging protocol, the charge load absorber matching charge load absorption characteristics of an EV.
